(19) United States
(12) Patent Application Publication
(10) Pub. No.: US 2025/0314482 A1
(43) Pub. Date: Oct. 9, 2025

(54) FOCUS POSITION MEASUREMENT WHILE SCANNING

(71) Applicant: KLA Corporation, Milpitas, CA (US)

(72) Inventors: Andrew V. Hill, Berkley, CA (US); Yuval Lubashevsky, Haifa (IL); Itay Gdor, Tel-Aviv (IL); Nickolai Isakovitch, Tel-Aviv (IL); Iftach Galon, Migdal Ha'emek (IL)

(21) Appl. No.: 18/630,417

(22) Filed: Apr. 9, 2024

(51) Int. Cl. G01B 11/27

(52) U.S. Cl. CPC G01B 11/27

(57) ABSTRACT

A system and method for adjusting a focus based on a scan are disclosed. The system may include an optical sub-system configured to detect light from a light modulation target of a sample as the sample is scanned along a scan direction. Two or more detection elements may be configured to detect the light modulation target at different points in time as the sample is scanned along the scan direction by virtue of a spatial separation between the two or more detection elements. The system may determine a time difference between different points in time that the light modulation target is detected during the scanning of the sample, determine a defocused value indicative of being under-focused or over-focused based on the time difference, and direct an adjustment of a focus of the optical sub-system based on the defocused value.

### TECHNICAL FIELD

The present disclosure relates generally to metrology and inspection systems, and, more particularly, to determining a focus of metrology and inspection systems.

### BACKGROUND

Adjusting a focus of a defocused metrology tool may face a variety of challenges. For example, focus contrast methods may measure focus by determining when the image is sharpest. Focus contrast methods typically require taking multiple images at several focus points. In some examples, this may be used to find the focus offset distance but may be time consuming and require full image reading and processing.

By way of another example, in an interferometric setup, the light may be split into a second objective over a mirror in the ideal field position and focus may be determined by monitoring the interference between the prime objective and the second objective. However, this method may be relatively costly, and may require splitting and reducing the illumination power to be sent exclusively for focus measurement. For instance, 50% of the illumination power may be used exclusively for focus measurement.

In another example, a bi-cell photo-diode setup may be utilized with an optical chopper located in an ideal field plane (with relation to the objective). However, this method may also use an additional measurement arm that reduces light beam power and the optical chopper may contribute to noise in metrology measurements by generating vibration and heat when it moves.

Overlay metrology refers to measurements of the relative alignment of layers on a sample such as, but not limited to, semiconductor devices. An overlay measurement, or a measurement of overlay error, typically refers to a measurement of the misalignment of fabricated features on two or more sample layers. Overlay may include the misalignment of features between different substrates, such as die alignment of dies stacked onto another substrate. Proper alignment is necessary for proper functioning of the device.

Demands to decrease feature size and increase feature density are resulting in correspondingly increased demand for accurate and efficient overlay metrology. Metrology systems typically determine metrology data associated with a sample by measuring or otherwise inspecting dedicated metrology targets (i.e., overlay targets) distributed across the sample. Accordingly, the sample is typically mounted on a translation stage and translated such that the metrology targets are sequentially moved into a measurement field of view.

### SUMMARY

A system is disclosed in accordance with one or more illustrative embodiments of the present disclosure. In one illustrative embodiment, the system may include an optical sub-system. In another illustrative embodiment, the optical sub-system may include one or more detectors configured to detect light from a light modulation target of a sample as the sample is scanned along a scan direction. In another illustrative embodiment, the one or more detectors may include two or more detection elements. In another illustrative embodiment, the two or more detection elements are configured to detect the light modulation target at different points in time as the sample is scanned along the scan direction by virtue of a spatial separation between the two or more detection elements. In another illustrative embodiment, the system may include a controller communicatively coupled to the one or more detectors. In another illustrative embodiment, the controller may include one or more processors configured to execute program instructions causing the one or more processors to acquire signals from the light modulation target using the two or more detection elements of the one or more detectors as the sample is scanned along the scan direction. In another illustrative embodiment, the one or more processors may determine, based on the signals, a time difference between the different points in time that the light modulation target is detected during the scanning of the sample. In another illustrative embodiment, the one or more processors may determine a defocused value indicative of the one or more detectors being under-focused or over-focused based on the time difference. In another illustrative embodiment, the one or more processors may direct an adjustment of a focus of the optical sub-system based on the defocused value.

In a further aspect, the defocused value may include a defocused distance based on the time difference. In another aspect, the defocused value may be further based on a scanning speed and an angle of diversion of an illumination beam at the light modulation target. In another aspect, the one or more detectors may be located in a pupil plane of the optical sub-system. In another aspect, the two or more detection elements may include four or more detection elements. In another aspect, a first set of the four or more detection elements may be configured for a first scan direction and a second set of the four or more detection elements may be configured for a second scan direction orthogonal to the first scan direction.

In a further aspect, the light modulation target may be configured to induce at least one of an intensity modulation or a phase modulation. In another aspect, the controller may be configured to continuously determine defocused values of a plurality of light modulation targets positioned along the scan direction and continuously direct adjustments of the focus of the optical sub-system based on the defocused values. In another aspect, the scanning along the scan direction may include a pre-scan and the controller may be further configured to direct a rescan of the light modulation target, where the light modulation target includes an overlay target, and determine an overlay measurement based on the rescan. In another aspect, the light modulation target may be spaced away from an overlay target, where the adjustment of the focus of the optical sub-system is configured to be performed during the scanning but before acquiring overlay signals from the overlay target. In another aspect, the one or more detectors may include a multi-pixel detector which includes the two or more detection elements. In another aspect, each of the two or more detection elements may include a single photo-diode detector. In another aspect, the scanning may include at least one of an actuation of a translation stage, or an adjustment of a component of the optical sub-system that is configured to scan an illumination spot along the scan direction.

A method for adjusting the focus of an optical sub-system is disclosed in accordance with one or more illustrative embodiments of the present disclosure. In one illustrative embodiment, the method may include acquiring signals from a light modulation target using two or more detection elements of one or more detectors as a sample is scanned along a scan direction. In another illustrative embodiment, the method may include determining a time difference between different points in time that the light modulation target is detected during the scanning of the sample. In another illustrative embodiment, the method may include determining a defocused value indicative of the one or more detectors being under-focused or over-focused based on the time difference. In another illustrative embodiment, the method may include directing an adjustment of the focus of an optical sub-system based on the defocused value. In another illustrative embodiment, the one or more detectors are configured to detect light from the light modulation target of the sample as the sample is scanned along the scan direction. In another illustrative embodiment, the one or more detectors may include two or more detection elements, which are configured to detect the light modulation target at different points in time as the sample is scanned along the scan direction by virtue of a spatial separation between the two or more detection elements.

In a further aspect, the defocused value may include a defocused distance based on the time difference. In another aspect, the defocused value may be further based on a scanning speed and an angle of diversion of an illumination beam at the light modulation target. In another aspect, the one or more detectors may be located in a pupil plane of the optical sub-system. In another aspect, the two or more detection elements may include four or more detection elements, where a first set of the four or more detection elements are configured for a first scan direction and a second set of the four or more detection elements are configured for a second scan direction orthogonal to the first scan direction. In another aspect, the light modulation target may be configured to induce at least one of an intensity modulation or a phase modulation. In another aspect, the method may further include continuously determining defocused values of a plurality of light modulation targets positioned along the scan direction and continuously directing adjustments of the focus of the optical sub-system based on the defocused values. In another aspect, the scanning along the scan direction may include a pre-scan and the method may further include directing a rescan of the light modulation target, where the light modulation target includes an overlay target, and determining an overlay measurement based on the rescan. In another aspect, the light modulation target may be spaced away from an overlay target, where the adjustment of the focus of the optical sub-system is performed during the scanning but before acquiring overlay signals from the overlay target. In another aspect, the one or more detectors may include a multi-pixel detector which includes the two or more detection elements. In another aspect, each of the two or more detection elements may include a single photo-diode detector. In another aspect, the scanning may include at least one of an actuation of a translation stage, or an adjustment of a component of the optical sub-system that is configured to scan an illumination spot along the scan direction.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1A illustrates a conceptual view of a system, in accordance with one or more embodiments of the present disclosure.

FIG. 1B illustrates a schematic view of an optical sub-system, in accordance with one or more embodiments of the present disclosure.

FIG. 2A illustrates a schematic view of detection elements of the optical sub-system in an overfocused state relative to a light modulation target of a sample, in accordance with one or more embodiments of the present disclosure.

FIG. 2B illustrates a chart of an intensity of illumination over time of the overfocused detection elements of FIG. 2A as the sample is scanned, in accordance with one or more embodiments of the present disclosure.

FIG. 3A illustrates a schematic view of detection elements in a focused state, in accordance with one or more embodiments of the present disclosure.

FIG. 3B illustrates a chart of an intensity of illumination over time of the focused detection elements of FIG. 3A as the sample is scanned, in accordance with one or more embodiments of the present disclosure.

FIG. 4A illustrates a schematic view of detection elements in an underfocused state, in accordance with one or more embodiments of the present disclosure.

FIG. 4B illustrates a chart of an intensity of illumination over time of the underfocused detection elements of FIG. 3A as the sample is scanned, in accordance with one or more embodiments of the present disclosure.

FIG. 5 illustrates a process flow diagram depicting a method for adjusting a focus, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

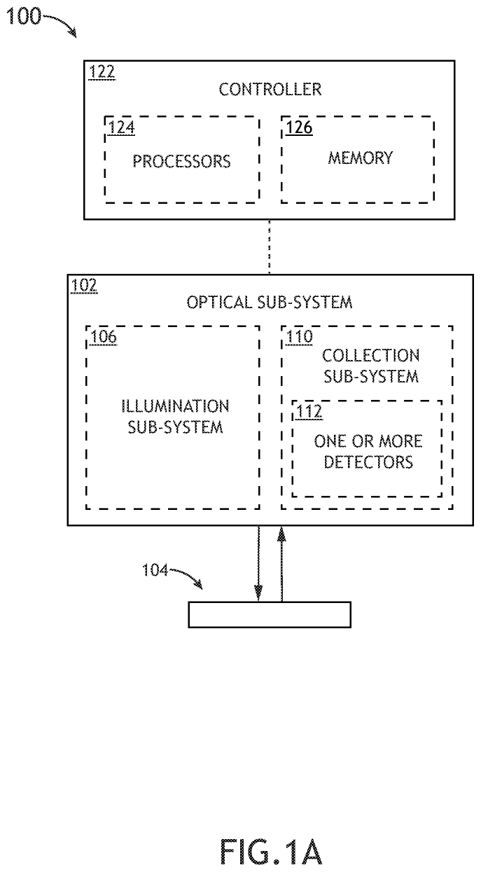

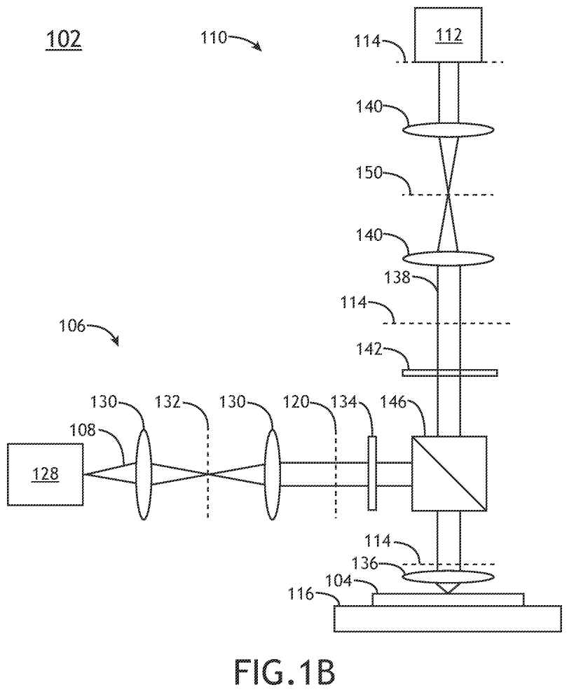

Referring to FIGS. 1A through 5, systems and methods for adjusting a focus during a scan of a sample based on a time difference of signals are disclosed, in accordance with one or more embodiments of the present disclosure.

Embodiments of the present disclosure are directed to the utilization of spatially separated detection elements (e.g., individual/single photodiodes or a multi-pixel camera) in a scanning mode to detect the lack of focus based on a difference in the time it takes for the spatially separated detection elements to detect a light modulation target (e.g., any feature/target of a sample that induces a change in phase and/or illumination). In embodiments, a mode of operation may include a detection of a change of an angular distribution of light from the light modulation target. To measure angular distributions, the detection elements may be at or near a pupil plane, or otherwise able to detect the angular distribution. In embodiments, various types of features may be used as a light modulation target, such as dedicated targets configured to modulate/change an illumination intensity and/or phase of light. In embodiments, an overlay target itself may be used as the light modulation target or a separate target may be used. The light modulation target may be positioned before an overlay target so that during a scan, the focus may be adjusted based on the light modulation target before reaching the overlay target. By way of another example, the overlay target itself may act as a light modulation target and may be rescanned after adjusting for focus.

Benefits of the present disclosure may include, but are not limited to, extraction of focus information in a scanning mode without necessarily needing to use separate sensors to determine focus information. In embodiments, the same setup used for scanning-based overlay metrology techniques with detectors in the pupil plane may be used as described herein for sensing and adjusting focus, without needing to necessarily add any hardware. Scanning-based scatterometry measurement techniques may include fast detectors to capture time-varying interference signals generated as the sample is scanned. The detectors may be placed in the pupil plane at locations of overlap between selected diffraction orders to capture time-varying interference signals as the sample is scanned. Various non-limiting scanning scatterometry overlay metrology techniques are described in U.S. Patent Publication No. 2022/0034652 filed on Feb. 17, 2021; U.S. patent application Ser. No. 17/119,536 filed on Dec. 11, 2020; U.S. patent application Ser. No. 17/708,958 filed on Mar. 30, 2022; and U.S. patent application Ser. No. 17/709,104 filed on Mar. 30, 2022; which are all incorporated herein by reference in their entireties. Note that such scanning examples are nonlimiting and embodiments herein may include various types of detectors such as one or more diode array sensors.

Also, measuring focus based on the sample itself—as described herein—may provide more accurate results compared to using an optical chopper in the optics of the system to measure focus.

FIG. 1A illustrates a conceptual view of a system 100 for adjusting a focus, in accordance with one or more embodiments of the present disclosure. The system 100 may include any system for any purpose. For example, the system 100 may include a metrology system. For example, the system 100 may include an inspection system. For example, the system may include an overlay metrology system configured for measuring overlay of a sample 104 (e.g., wafer).

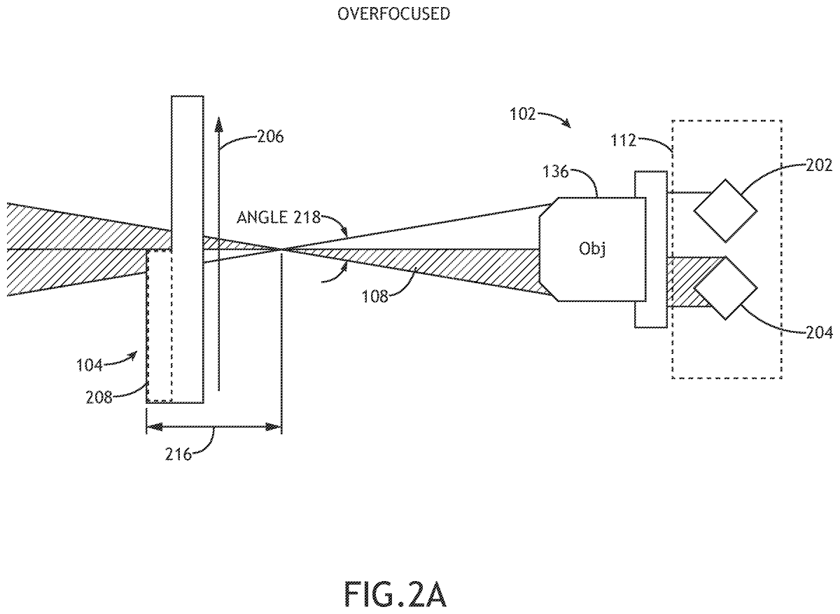

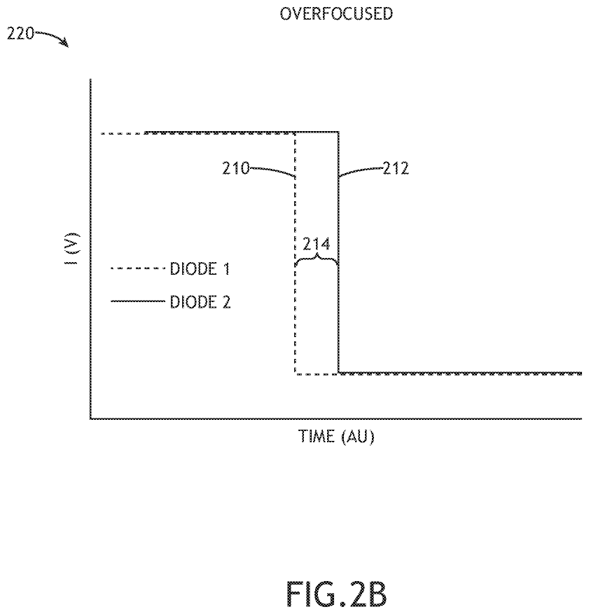

In embodiments, the system 100 includes an optical sub-system 102 to perform measurements on sample 104. In embodiments, the sample 104 includes some sort of feature/element (or lack thereof) configured to induce a change in the angular distribution of light as it passes through an unfocused portion of the illumination beam. For example, the portion/element/feature configured to induce the change in the angular distribution may be referred to as a light modulation target. See FIG. 2A for an example of a light modulation target 208 and detection elements 202, 204. A difference in time that the change in the angular distribution of light is detected may be used to determine the focus.

In embodiments, the light modulation target 208 may be configured to induce an illumination intensity modulation. For example, the light modulation target 208 may include, but is not limited to, a coating (e.g., anti-reflective coating) that causes the first detection element 202 to detect a drop in light intensity emanating from the sample at an earlier point in time than the second detection element 204 as an illumination beam 108 is scanned across the sample 104. By way of another example, the light modulation target 208 may include a layer. For instance, the layer may be configured to be semi-transparent, and thereby reduce the illumination that passes through it. Other examples include reflective layers (e.g., layers that are more reflective than the surrounding areas). These are nonlimiting examples, and any feature, layer, coating, and/or the like may be used that—compared to surrounding areas—has different effective optical properties (e.g., thickness, density, reflectivity, transparency, luminescence, polarization sensitivity, refractive index, and/or the like or any combination thereof). The choice of the light modulation target may depend on the specific application, wavelength range, and desired intensity modulation characteristics.

In embodiments, the light modulation target 208 may be configured to induce a phase modulation. For example, the light modulation target 208 may include, but is not limited to, a transparent material with a different refractive index than the surrounding area, causing a phase shift in light passing through it. This phase shift can be detected by the first detection element 202 at a different time compared to the second detection element 204 as the illumination beam 108 is scanned across the sample 104. The light modulation target 208 may include structures such as layers of material, gratings, or other features to introduce phase shifts in light based on their geometry, periodicity, material properties, or the like.

The light modulation target 208 may include any shape. For example, the light modulation target 208 may be a rectangular or square shape along a scan path.

In embodiments, the optical sub-system 102 includes an illumination sub-system 106 and a collection sub-system 110. The collection sub-system 110 may include a detector 112.

In embodiments, the system 100 includes a controller 122 communicatively coupled to the optical sub-system 102. The controller 122 may include one or more processors 124 and a memory device 126, or memory. For example, the one or more processors 124 may be configured to execute a set of program instructions maintained in the memory device 126.

FIG. 1B illustrates a schematic view of the optical sub-system 102, in accordance with one or more embodiments of the present disclosure. The illumination sub-system 106 is configured to generate illumination in the form of one or more illumination beams 108 to illuminate the sample 104. The collection sub-system 110 is configured to collect light 138 from the illuminated sample 104. Further, the one or more illumination beams 108 may be spatially limited such that they illuminate selected portions of the sample 104. For instance, each of the one or more illumination beams 108 may be spatially limited to illuminate a particular overlay target.

The detector 112 may include any detector 112 known in the art of metrology. For example, the detector 112 may include, but is not limited to, photodiodes (e.g., two or more photodiodes). For example, a photodiode may be referred to as a photo-diode detector. For instance, the detector 112 may include two or more, or four or more photodiodes. In some embodiments, the photodiodes include photodiodes having a bandwidth of at least 1 GHz. However, it is to be understood that this value is not a requirement. Rather, the bandwidth of the photodiodes and the scanning speed along the scan direction may be selected together to provide a desired sampling rate of the signal. By way of another example, the detector 112 may include, but is not limited to, a multi-pixel detector such as a complementary metal-oxide semiconductor (CMOS) detector, a charge-coupled device (CCD) detector, or the like. For example, each detection element 202, 204 may correspond to a particular pixel or group of pixels of the multi-pixel detector 112.

The one or more detectors 112 may be located in a pupil plane 114 of the collection sub-system 110.

In embodiments, the optical sub-system 102 includes a translation stage 116 to move the sample 104 through a measurement field of view of the optical sub-system 102 during a scan. By way of another example, the sample may be scanned by an adjustment (e.g., angling) of a component (e.g., any component of FIG. 1B such as lens 136) of the optical sub-system 102 that is configured to scan an illumination spot along a scan direction.

In embodiments, the optical sub-system 102 includes an objective lens 136 to focus the illumination beam 108 onto the sample 104. For example, the objective lens 136 may be configured to collect measurement light 138 emanating from a sample 104 in response to the illumination beam 108 according to a metrology recipe.

The optical sub-system 102 may include one or more beamsplitters 146 for splitting light, such as for splitting the illumination beam 108.

System 100 may be configured for certain types of samples or features of a sample 104 according to a “metrology recipe.” For example, the system 100 may be programmed to calculate overlay measurements of certain types of features according to a metrology recipe.

FIGS. 2A, 3A, and 4A illustrate schematic views of the optical sub-system 102 in an underfocused, focused, and overfocused state, respectively. FIGS. 2B, 3B, and 4B illustrate charts of light intensities over time of the underfocused, focused, and overfocused states, respectively. It is to be understood, however, that the samples 104 and light modulation target 208 in FIGS. 2A-4B and the associated descriptions are provided solely for illustrative purposes and should not be interpreted as limiting. Rather, the sample 104 and light modulation target 208 may include any suitable design and configuration.

FIG. 2A illustrates a schematic view of detection elements 202, 204 of the optical sub-system 102 in an overfocused state relative to a light modulation target 208 of a sample 104, in accordance with one or more embodiments of the present disclosure. FIG. 2B illustrates a chart 220 of intensities 210, 212 of illumination over time corresponding to the overfocused detection elements 202, 204 of FIG. 2A as the sample 104 is scanned, in accordance with one or more embodiments of the present disclosure.

As shown in FIG. 2B, the light intensities 210, 212 drop due to the movement of the sample 104 at different points in time. The difference between these points in time may be referred to as a time difference 214. The time difference 214 may exist by virtue of the detection elements 202, 204 being spaced apart relative to each other and relative to the scan direction. For example, a target may impact the angular distribution of light as it sweeps/scans through an unfocused part of the illumination. When this happens, the length span of this variation may be indicative of a degree of defocus, and the direction may be indicative of under/overfocus.

As the degree/amount of defocus (e.g., underfocus or overfocus) increases, so does the time difference 214. The controller 122 may be configured to determine a calibration and/or use a calibration based on the time difference 214. For example, the calibration may correlate the time difference 214 (e.g., quantity of picoseconds) to a correction distance 216 potentially needed to adjust/correct for the amount of defocused state. For example, the correction distance 216 may be an amount needed to move an actuator to bring the sample 104 closer using the translation stage 116 or the like.

The defocused value may be based on a scanning speed and an angle of diversion 218 of an illumination beam 108 at the light modulation target 208.

An equation for a focus deviation (e.g., defocused value, defocus distance 216) may be as follows:

$$Focus deviation = \frac{V Δ t}{2 tan ( θ )} = \frac{V Δ t}{2 NA} \sqrt{1 - {NA}^{2}} \qquad ( Eq . 1 )$$

where V is the scanning speed (e.g., how fast the illumination beam 108 is scanned across the sample 104), θ is an angle of diversion 218 of the illumination beam at the sample, Δt is the time difference 214, and NA is the numerical aperture of the illumination pathway 106 (e.g., an average numerical aperture value).

For scanning, the sample 104 may be moved in a sample movement direction 206 using the translation stage 116. A spot of the illumination beam 108 may, alternatively and/or in addition, be scanned along the sample 104. The sample movement direction 206 may be opposite the scan direction.

In embodiments, the sample 104 includes any number of light modulation targets 208. For example, the sample 104 may be a wafer including light modulation targets 208 in a scribe line of the wafer. For example, the optical sub-system 102 may be configured to continuously scan a series of light modulation targets 208 to continuously adjust the focus of the sample 104 to keep the sample 104 in focus and determine measurements across the sample 104. For instance, the same detection elements 202, 204 (e.g., photodiodes) used to determine defocused values and adjust the focus may also be used for overlay measurements. The light modulation targets 208 may be spaced away from the overlay targets so that the focus may be adjusted before the scan reaches the overlay target.

In a static measurement mode, the system 100 may be configured, when moving between static targets (e.g., overlay targets measured when static), to perform a scan of light modulation targets 208 between the static targets to adjust for focus on the move. This may allow for increasing throughput by eliminating a need to adjust for focus after arriving at the static target. For example, in other methods, static targets may be imaged along a depth direction to determine focus by looking at where the images are the least blurry. In some embodiments of the present disclosure, such a depth direction scan may be eliminated. Static measurement modes may include a variety of modes such as scatterometry overlay (SCOL), and/or image-based overlay (IBO). For example, IBO metrology methods may use grating patterns of dedicated overlay targets located in a scribe line of a wafer. For instance, optically-resolvable targets may be on the order of more than 10 microns (e.g., 30 microns) in size.

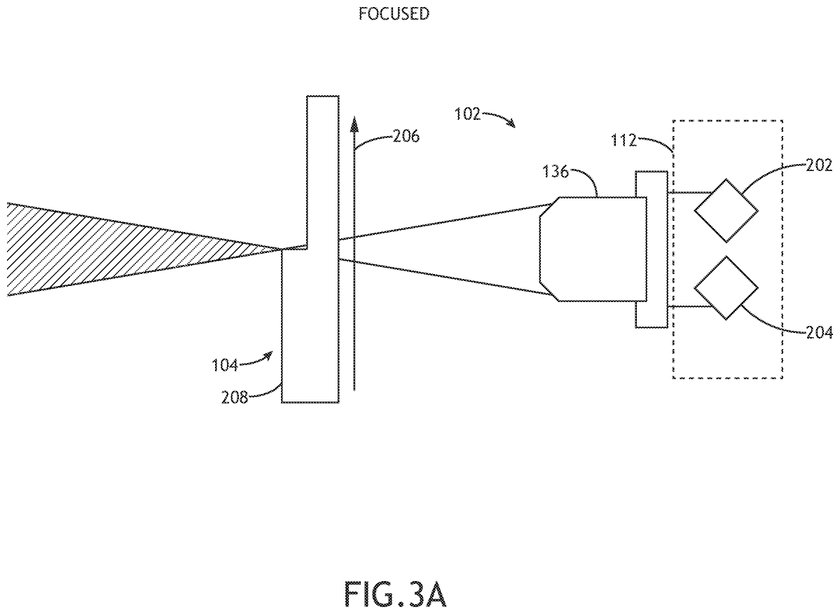

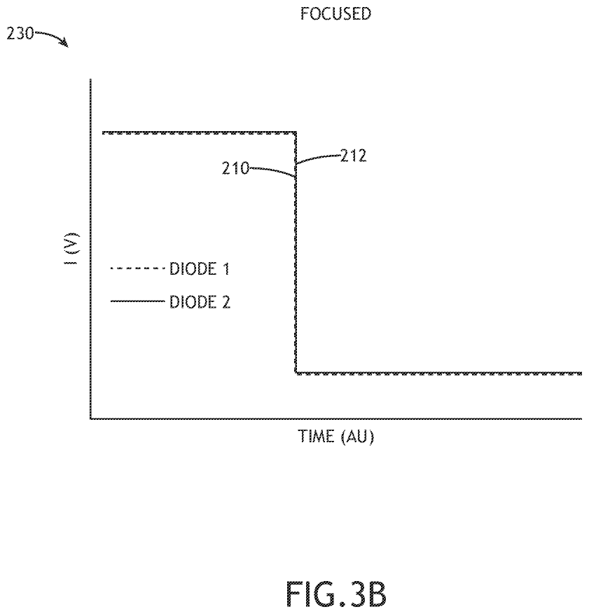

FIG. 3A illustrates a schematic view of detection elements 202, 204 in a focused state, in accordance with one or more embodiments of the present disclosure. FIG. 3B illustrates a chart 230 of intensities 210, 212 of illumination over time of the focused detection elements 202, 204 of FIG. 3A as the sample 104 is scanned, in accordance with one or more embodiments of the present disclosure.

When the illumination beam 108 is focused, then changes detected by the detection elements 202, 204 may occur at the same (or nearly the same) points in time, such as a drop in the intensities 210, 212 occurring at the same time in FIG. 3B.

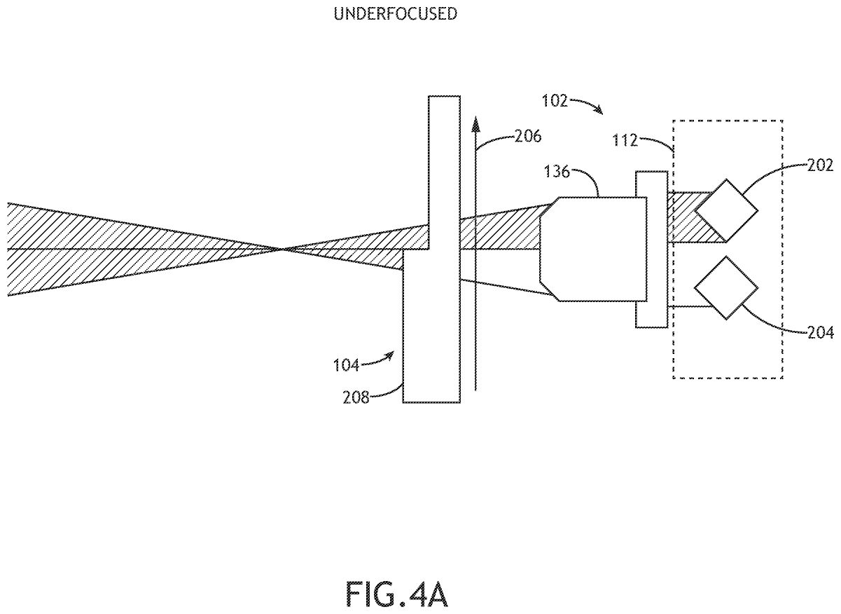

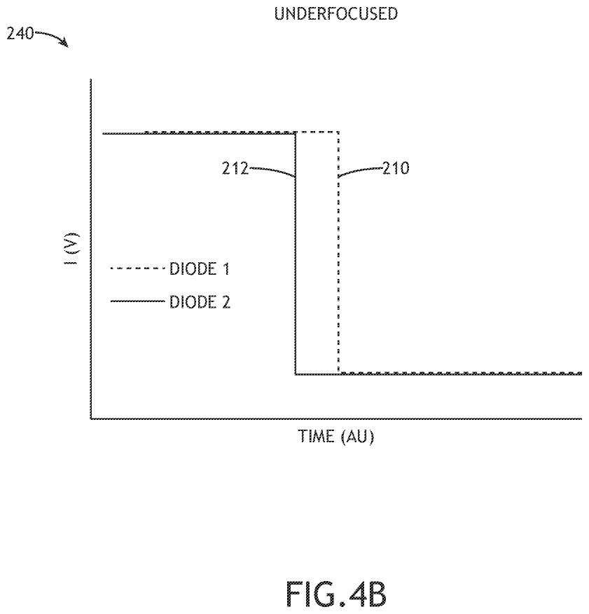

FIG. 4A illustrates a schematic view of detection elements 202, 204 in an underfocused state, in accordance with one or more embodiments of the present disclosure. FIG. 4B illustrates a chart 240 of intensities 210, 212 of illumination over time of the underfocused detection elements 202, 204 of FIG. 3A as the sample 104 is scanned, in accordance with one or more embodiments of the present disclosure.

An underfocused state may cause an opposite detection element to be affected at an earlier point in time than an overfocused state. This difference in order may be used to differentiate between an overfocused or underfocused state. In this way, not only may the amount of defocus be determined, but the type of defocus (e.g., overfocus or underfocus) may also be determined. For example, FIG. 4B illustrates the first intensity 210 corresponding to the first detection element 202 is now affected last in time, which is opposite to FIG. 2B for an overfocused state.

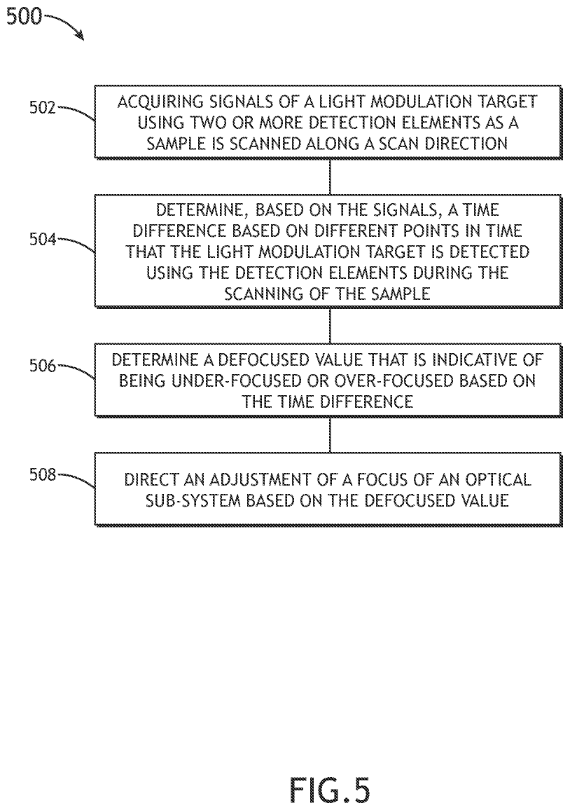

FIG. 5 illustrates a process flow diagram depicting a method 500 for adjusting a focus, in accordance with one or more embodiments of the present disclosure. It is noted that the embodiments and enabling technologies described previously herein in the context of the system 100 should be interpreted to extend to the method 500. It is further noted herein that the steps of method 500 may be implemented all or in part by system 100. It is further recognized, however, that the method 500 is not limited to the system 100 in that additional or alternative system-level embodiments may carry out all or part of the steps of method 500.

In step 502, signals from a light modulation target 208 are acquired using two or more detection elements 202, 204 as a sample 104 is scanned along a scan direction.

For example, time-varying signals of photodiodes may be received and recorded to memory 126. By way of another example, the optical sub-system 102 may capture/acquire/receive an image (e.g., a series of images over time) using a multipixel detector 112 with two of the pixel sensors of the multipixel detector 112 being a respective detection element 202, 204.

In step 504, a time difference 214 is determined based on different points in time that the light modulation target 208 is detected using the detection elements 202, 204 during the scanning of the sample 104. For example, a drop or rise or jiggling or the like of the intensity over time may be configured through a software to be detected and correspond to a point in time that such an event occurred or started to occur or the like. For example, a change in phase may be configured to be detected. For instance, the controller 122 may be configured to use a threshold to determine the points in time. For example, the threshold could be any threshold, such as a drop in intensity of more than 1% from an average intensity, of more than 3%, and/or the like.

In step 506, a defocused value indicative of being under-focused or over-focused based on the time difference 214 is determined. For example, the defocused value may, but is not necessarily required to be, proportional to a defocused distance 216 as shown in FIG. 2A. For instance, a defocused value of −0.XX (negative) may be overfocused and +0.XX (overfocused) may be underfocused, or vice versa.

In step 508, an adjustment of a focus of an optical sub-system 102 based on the defocused value is directed. For example, the controller 122 may direct (e.g., transmit a signal to an actuator controller or actuator) an adjustment to the height of the sample 104 relative to a focal point.

In another step (not shown), based on acquired signals (e.g., detection element signals), overlay measurements corresponding to overlay targets are determined. For example, the controller 122 may compare the magnitudes and/or phases of the detection signals to generate an overlay measurement. For instance, U.S. Pat. No. 10,824,079 issued on Nov. 3, 2020 incorporated herein by reference in its entirety generally describes diffracted orders in a collection pupil and further provides specific relationships between overlay and measured intensity in the pupil plane.

In another step (not shown), one or more processes of a manufacturing of the sample 104 are controlled based on the overlay measurements. This may involve adjusting the parameters of the process (such as light frequency, intensity, or processing time) in order to minimize the overlay. The adjustments may be made manually by an operator, or automatically by a control system in response to the overlay measurement. For example, if the overlay measurement is greater than a predetermined threshold, then the process parameter(s) might be adjusted to reduce the overlay. Conversely, if the overlay measurement is less than the threshold, then the process parameter(s) might be left unchanged, or possibly adjusted to decrease the overlay slightly in order to keep it within an optimal range. Such processes may include semiconductor manufacturing, photolithography, and many others.

In another step (not shown), scans are performed in two different directions (e.g., an X-direction orthogonal to a Y-direction). To achieve this, two sets of detection elements may be used, such as a diamond arrangement of four. The arrangement may include two vertically aligned detection elements for a first direction and two horizontally aligned detection elements for a second direction. For example, the detection elements may include four or more detection elements. The first set of the four or more detection elements may be configured for a first scan direction and a second set of the four or more detection elements may be configured for a second scan direction orthogonal to the first scan direction.

In embodiments, the system 100 may be programmed to perform a pre-scan of an overlay target to adjust the focus and then rescan the overlay target. Then overlay may be determined based on time-varying signals of the detector 112 as measured from the overlay target, such as signals obtained from overlapping diffraction orders in the pupil plane. For example, the signals of step 502 may include (or be) a pre-scan of an overlay target for measuring focus. Then the same overlay target may be rescanned (i.e., scanned again such as by backing up and rescanning in the same direction, scanning in a reverse direction, and/or the like). In this regard, a single light modulation target (e.g., overlay target) may be used both to determine focus and then for determining a property (e.g., overlay) of the sample 104.

Referring again to FIGS. 1A-1B, various components are described in greater detail in accordance with one or more embodiments of the present disclosure.

The one or more processors 124 of the controller 122 may include any processor or processing element known in the art. For the purposes of the present disclosure, the term “processor” or “processing element” may be broadly defined to encompass any device having one or more processing or logic elements (e.g., one or more microprocessor devices, one or more application specific integrated circuit (ASIC) devices, one or more field programmable gate arrays (FPGAs), or one or more digital signal processors (DSPs)). In this sense, the one or more processors 124 may include any device configured to execute algorithms and/or instructions (e.g., program instructions stored in memory). In embodiments, the one or more processors 124 may be embodied as a desktop computer, mainframe computer system, workstation, image computer, parallel processor, networked computer, or any other computer system configured to execute a program configured to operate or operate in conjunction with the system 100, as described throughout the present disclosure. Moreover, different subsystems of the system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers. Additionally, the controller 122 may include one or more controllers housed in a common housing or within multiple housings. In this way, any controller or combination of controllers may be separately packaged as a module suitable for integration into system 100. Further, the controller 122 may analyze or otherwise process data received from the one or more detectors 112 and feed the data to additional components within the system 100 or external to the system 100.

Further, the memory device 126 may include any storage medium known in the art suitable for storing program instructions executable by the associated one or more processors 124. For example, the memory device 126 may include a non-transitory memory medium. As an additional example, the memory device 126 may include, but is not limited to, a read-only memory, a random-access memory, a magnetic or optical memory device (e.g., disk), a magnetic tape, a solid-state drive and the like. It is further noted that memory device 126 may be housed in a common controller housing with the one or more processors 124.

In this regard, the controller 122 may execute any of various processing steps. For example, the controller 122 may be configured to generate control signals to direct or otherwise control the optical sub-system 102, or any components thereof. For instance, the controller 122 may be configured to receive signals corresponding to the signals from the one or more detectors 112. By way of another example, the controller 122 may generate correctables for one or more additional fabrication tools as feedback and/or feed-forward control of the one or more additional fabrication tools based on overlay measurements from the optical sub-system 102.

Further, the controller 122 may calibrate or otherwise modify the overlay measurement based on known, assumed, or measured features of the sample 104 that may also impact the signals such as, but not limited to, sidewall angles or other sample asymmetries.

Referring again to FIG. 1B, various components of the optical sub-system 102 are described in greater detail in accordance with one or more embodiments of the present disclosure.

In embodiments, the illumination sub-system 106 includes an illumination source 128 configured to generate at least one illumination beam 108. The illumination from the illumination source 128 may include one or more selected wavelengths of light including, but not limited to, ultraviolet (UV) radiation, visible radiation, or infrared (IR) radiation.

The illumination source 128 may include any type of illumination source suitable for providing at least one illumination beam 108. In embodiments, the illumination source 128 is a laser source. For example, the illumination source 128 may include, but is not limited to, one or more narrowband laser sources, a broadband laser source, a supercontinuum laser source, a white light laser source, or the like. In this regard, the illumination source 128 may provide an illumination beam 108 having high coherence (e.g., high spatial coherence and/or temporal coherence). In embodiments, the illumination source 128 includes a laser-sustained plasma (LSP) source. For example, the illumination source 128 may include, but is not limited to, a LSP lamp, a LSP bulb, or a LSP chamber suitable for containing one or more elements that, when excited by a laser source into a plasma state, may emit broadband illumination.

In embodiments, the illumination sub-system 106 includes one or more optical components suitable for modifying and/or conditioning the illumination beam 108 as well as directing the illumination beam 108 to the sample 104. For example, the illumination sub-system 106 may include one or more illumination lenses 130 (e.g., to collimate the illumination beam 108, to relay an illumination pupil plane 120 and/or an illumination field plane 132, or the like). In embodiments, the illumination sub-system 106 includes one or more illumination control optics 134 to shape or otherwise control the illumination beam 108. For example, the illumination control optics 134 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

The collection sub-system 110 may include one or more optical elements suitable for modifying and/or conditioning the collected light 138 from the sample 104. In embodiments, the collection sub-system 110 includes one or more collection lenses 140. In embodiments, the collection sub-system 110 includes one or more collection control optics 142 to shape or otherwise control the collected light 138. For example, the collection control optics 142 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like). In another example, the collection sub-system 110 may include one or more collection field planes 150.

Referring again to FIG. 1A, it is noted herein that the one or more components of system 100 may be communicatively coupled to the various other components of system 100 in any manner known in the art. For example, the one or more processors 124 may be communicatively coupled to each other and other components via a wireline (e.g., copper wire, fiber optic cable, and the like) or wireless connection (e.g., RF coupling, IR coupling, WiMax, Bluetooth, 3G, 4G, 4G LTE, 5G, and the like). By way of another example, the controller 122 may be communicatively coupled to one or more components of optical sub-system 102 via any wireline or wireless connection known in the art.

In embodiments, the one or more processors 124 may include any one or more processing elements known in the art. In this sense, the one or more processors 124 may include any microprocessor-type device configured to execute software algorithms and/or instructions. In embodiments, the one or more processors 124 may consist of a desktop computer, mainframe computer system, workstation, image computer, parallel processor, or other computer system (e.g., networked computer) configured to execute a program configured to operate the system 100, as described throughout the present disclosure. It should be recognized that the steps described throughout the present disclosure may be carried out by a single computer system or, alternatively, multiple computer systems. Furthermore, it should be recognized that the steps described throughout the present disclosure may be carried out on any one or more of the one or more processors 124. In general, the term “processor” may be broadly defined to encompass any device having one or more processing elements, which execute program instructions from memory 126. Moreover, different subsystems of the system 100 may include processor or logic elements suitable for carrying out at least a portion of the steps described throughout the present disclosure. Therefore, the above description should not be interpreted as a limitation on the present disclosure but merely an illustration.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary.

The previous description is presented to enable one of ordinary skill in the art to make and use the invention as provided in the context of a particular application and its requirements. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

We claim:

1. A system comprising:
an optical sub-system comprising:
one or more detectors configured to detect light from a light modulation target of a sample as the sample is scanned along a scan direction, wherein the one or more detectors comprise:
two or more detection elements, wherein the two or more detection elements are configured to detect the light modulation target at different points in time as the sample is scanned along the scan direction by virtue of a spatial separation between the two or more detection elements; and
a controller communicatively coupled to the one or more detectors and including one or more processors configured to execute program instructions causing the one or more processors to:
acquire signals from the light modulation target using the two or more detection elements of the one or more detectors as the sample is scanned along the scan direction,
determine, based on the signals, a time difference between the different points in time that the light modulation target is detected during the scanning of the sample;
determine a defocused value indicative of the one or more detectors being under-focused or over-focused based on the time difference; and
direct an adjustment of a focus of the optical sub-system based on the defocused value.

2. The system of claim 1,
wherein the defocused value comprises a defocused distance based on the time difference.

3. The system of claim 1,
wherein the defocused value is further based on a scanning speed and an angle of diversion of an illumination beam at the light modulation target.

4. The system of claim 1, wherein the one or more detectors are located in a pupil plane of the optical sub-system.

5. The system of claim 1, wherein the two or more detection elements comprise four or more detection elements, wherein a first set of the four or more detection elements are configured for a first scan direction and wherein a second set of the four or more detection elements are configured for a second scan direction orthogonal to the first scan direction.

6. The system of claim 1, wherein the light modulation target is configured to induce at least one of: an intensity modulation or a phase modulation.

7. The system of claim 1, wherein the controller is configured to:
continuously determine defocused values of a plurality of light modulation targets positioned along the scan direction and continuously direct adjustments of the focus of the optical sub-system based on the defocused values.

8. The system of claim 1, wherein the scanning along the scan direction comprises a pre-scan and wherein the controller is further configured to:
direct a rescan of the light modulation target, wherein the light modulation target comprises an overlay target; and
determine an overlay measurement based on the rescan.

9. The system of claim 1, wherein the light modulation target is spaced away from an overlay target,
wherein the adjustment of the focus of the optical sub-system is configured to be performed during the scanning but before acquiring overlay signals from the overlay target.

10. The system of claim 1, wherein the one or more detectors comprise a multi-pixel detector which comprises the two or more detection elements.

11. The system of claim 1, wherein each of the two or more detection elements comprise a single photo-diode detector.

12. The system of claim 1, wherein the scanning comprises at least one of: an actuation of a translation stage, or an adjustment of a component of the optical sub-system that is configured to scan an illumination spot along the scan direction.

13. A method comprising:
acquiring signals from a light modulation target using two or more detection elements of one or more detectors as a sample is scanned along a scan direction,
determine, based on the signals, a time difference between different points in time that the light modulation target is detected during the scanning of the sample;
determine a defocused value indicative of the one or more detectors being under-focused or over-focused based on the time difference; and
direct an adjustment of a focus of an optical sub-system based on the defocused value,
wherein the one or more detectors are configured to detect light from the light modulation target of the sample as the sample is scanned along the scan direction, wherein the one or more detectors comprise:
two or more detection elements, wherein the two or more detection elements are configured to detect the light modulation target at the different points in time as the sample is scanned along the scan direction by virtue of a spatial separation between the two or more detection elements.

14. The method of claim 13,
wherein the defocused value comprises a defocused distance based on the time difference.

15. The method of claim 13,
wherein the defocused value is further based on a scanning speed and an angle of diversion of an illumination beam at the light modulation target.

16. The method of claim 13, wherein the one or more detectors are located in a pupil plane of the optical sub-system.

17. The method of claim 13, wherein the two or more detection elements comprise four or more detection elements, wherein a first set of the four or more detection elements are configured for a first scan direction and wherein a second set of the four or more detection elements are configured for a second scan direction orthogonal to the first scan direction.

18. The method of claim 13, wherein the light modulation target is configured to induce at least one of: an intensity modulation or a phase modulation.

19. The method of claim 13, further comprising:
continuously determining defocused values of a plurality of light modulation targets positioned along the scan direction and continuously directing adjustments of the focus of the optical sub-system based on the defocused values.

20. The method of claim 13, wherein the scanning along the scan direction comprises a pre-scan and further comprising:
directing a rescan of the light modulation target, wherein the light modulation target comprises an overlay target; and
determining an overlay measurement based on the rescan.

21. The method of claim 13, wherein the light modulation target is spaced away from an overlay target,
wherein the adjustment of the focus of the optical sub-system is performed during the scanning but before acquiring overlay signals from the overlay target.

22. The method of claim 13, wherein the one or more detectors comprise a multi-pixel detector which comprises the two or more detection elements.

23. The method of claim 13, wherein each of the two or more detection elements comprise a single photo-diode detector.

24. The method of claim 13, wherein the scanning comprises at least one of: an actuation of a translation stage, or an adjustment of a component of the optical sub-system that is configured to scan an illumination spot along the scan direction.
